(19) United States
(12) Patent Application Publication
(10) Pub. No.: US 2022/0066521 A1
(43) Pub. Date: Mar. 3, 2022

(54) BEND-RESISTANT WIRE, PREPARATION METHOD THEREFOR AND FLEXIBLE DISPLAY PANEL

(71) Applicant: SHENZHEN ROYOLE TECHNOLOGIES CO., LTD., Shenzhen (CN)

(72) Inventors: Weihua JIA, Shenzhen (CN); Changming QIU, Shenzhen (CN)

(21) Appl. No.: 17/411,253

(22) Filed: Aug. 25, 2021

(30) Foreign Application Priority Data
Aug. 25, 2020 (CN) 202010875951.9

(51) Int. Cl. G06F 1/18; G06F 1/16; H01B 7/00; H01B 7/04; H01B 13/06

(52) U.S. Cl. CPC G06F 1/189; G06F 1/1652; H01B 13/06; H01B 7/04; H01B 7/0081

(57) ABSTRACT

The present disclosure provides a bend-resistant wire, a preparation method therefor and a flexible display panel, and relates to the field of display technologies. The bend-resistant wire is formed on a side surface of a flexible substrate of a flexible display panel that is located in a fan-out region, the bend-resistant wire includes a conductive layer, the conductive layer has hollow parts formed corresponding to a bent region of the flexible substrate, and an area of each of the hollow parts in the bent region is positively correlated with a curvature of the corresponding bent region. An objective of the present disclosure is to provide the bend-resistant wire, the preparation method therefor and the flexible display panel, which can reduce a risk that a fan-out wire of the flexible display panel breaks when the flexible display panel is bent.

### TECHNICAL FIELD

The present disclosure relates to the field of display technologies, and in particular, to a bend-resistant wire, a preparation method therefor and a flexible display panel.

### BACKGROUND ART

With the rapid development of electronic technologies, competition in the electronic product industry has become more and more fierce, and users also pose increasingly higher requirements for the performance and appearance of electronic products such as mobile phones. To improve the aesthetics of mobile phones and other electronic products, and to provide more comfortable interactive experience, display apparatuses with a high screen-to-body ratio (i.e., display apparatuses with a relatively high proportion of display region) have become a hot spot.

At present, common display apparatuses with a high screen-to-body ratio are generally implemented by using a technology featuring a small bending radius for the lower bezel (the bending radius R is usually less than 0.5 mm), so that the display apparatuses have a reduced width for the lower bezel to further increase the screen-to-body ratio of the display apparatuses. However, because the bezel of the display apparatuses needs to be bent by a small radius, a fan-out wire arranged in a fan-out region of the bezel often breaks due to the bending, resulting in a low yield and poor performance stability of the display apparatuses with a high screen-to-body ratio.

### SUMMARY OF THE INVENTION

An objective of the present disclosure is to provide a bend-resistant wire, a preparation method therefor and a flexible display panel, which can reduce a risk that a fan-out wire of the flexible display panel breaks when the flexible display panel is bent.

Embodiments of the present disclosure are implemented as follows:

According to an aspect of the embodiments of the present disclosure, a bend-resistant wire is provided, where the bend-resistant wire is formed on a side surface of a flexible substrate of a flexible display panel that is located in a fan-out region, the bend-resistant wire includes a conductive layer, the conductive layer has hollow parts formed corresponding to a bent region of the flexible substrate, and an area of each of the hollow parts in the bent region is positively correlated with a curvature of the corresponding bent region.

Optionally, in a bending direction of the bent region, the area of each of the hollow parts in regions at two ends of the conductive layer is smaller than the area of each of the hollow parts in a central region of the conductive layer.

Optionally, the areas of the hollow parts gradually decrease from the central region to the regions at the two ends of the conductive layer.

Optionally, the hollow parts are through holes arranged in the conductive layer.

Optionally, the through holes are arranged in multiple columns in the bending direction of the bent region.

Optionally, shapes of the through holes are one or a combination of several of a circle, an ellipse, a triangle and a polygon.

Optionally, the conductive layer has a wire mesh structure, and meshes of the wire mesh structure are the hollow parts.

Optionally, shapes of the meshes include any one of a triangle, a quadrilateral and a hexagon.

Optionally, the conductive layer includes at least two wire layers stacked on each other.

Optionally, the conductive layer is composed of multiple rhombic conductive bezels connected in sequence by vertices, regions enclosed by the rhombuses are the hollow parts, the rhombuses are arranged in sequence along straight lines where first diagonal lines of the rhombuses are located, and second diagonal lines of the rhombuses are all equal in length, where the first diagonal lines are each parallel to the bending direction of the bent region.

According to another aspect of the embodiments of the present disclosure, a preparation method for a bend-resistant wire is provided, including:

forming a conductive layer on a flexible substrate of a flexible display panel, and forming hollow parts on the conductive layer, where the conductive layer is located in a fan-out region of the flexible display panel, the hollow parts correspond to a bent region of the flexible substrate, and an area of each of the hollow parts in the bent region is positively correlated with a curvature of the corresponding bent region.

Optionally, the forming a conductive layer on a flexible substrate of a flexible display panel, and forming hollow parts on the conductive layer includes:

fitting a bending curve of the bent region to obtain a fitted curve;

calculating a curvature of each position of the bent region based on the fitted curve; and

forming the conductive layer with the hollow parts on the flexible substrate based on the curvature.

According to still another aspect of the embodiments of the present disclosure, a flexible display panel is provided, where the bend-resistant wire according to any one of the above implementations is used as a fan-out wire in a fan-out region of the flexible display panel.

The embodiments of the present disclosure have the following beneficial effects:

A bend-resistant wire provided in an embodiment of the present disclosure is formed on a side surface of a flexible substrate of a flexible display panel that is located in a fan-out region. In practice, the bend-resistant wire may be routed based on a specific circuit design, so as to use the bend-resistant wire as a fan-out wire to implement communication connection between a drive circuit and a drive chip of the flexible display panel. The bend-resistant wire is composed of a conductive layer, and the conductive layer has hollow parts formed corresponding to a bent region of the flexible substrate. The hollow parts formed on the conductive layer can reduce a bending stress borne by a part of the conductive layer in the bent region of the flexible substrate when the flexible substrate is bent. As such, the bending resistance of the bend-resistant wire is improved, and when the flexible substrate is bent, the wire thereon is not prone to breakage, which reduces a risk of poor electrical properties when the flexible substrate (the flexible display panel) is bent.

### BRIEF DESCRIPTION OF THE DRAWINGS

To describe the technical solutions in the embodiments of the present disclosure more clearly, the following briefly describes the accompanying drawings required in the embodiments. It should be understood that the following accompanying drawings show merely some embodiments of the present disclosure and thus should not be considered as a limitation on the scope, and a person of ordinary skill in the art may still derive other related accompanying drawings from these accompanying drawings without creative efforts.

FIG. 1 is a schematic structural diagram illustrating a hierarchical arrangement of a bend-resistant wire according to an embodiment of the present disclosure;

FIG. 2 is schematic structural diagram 1 illustrating a bend-resistant wire according to an embodiment of the present disclosure;

FIG. 3 is schematic structural diagram 2 illustrating a bend-resistant wire according to an embodiment of the present disclosure;

FIG. 4 is schematic structural diagram 3 illustrating a bend-resistant wire according to an embodiment of the present disclosure;

FIG. 5 is schematic structural diagram 4 illustrating a bend-resistant wire according to an embodiment of the present disclosure;

FIG. 6 is schematic structural diagram 5 illustrating a bend-resistant wire according to an embodiment of the present disclosure;

FIG. 7 is schematic structural diagram 6 illustrating a bend-resistant wire according to an embodiment of the present disclosure;

FIG. 8 is schematic structural diagram 7 illustrating a bend-resistant wire according to an embodiment of the present disclosure;

FIG. 9 is schematic structural diagram 8 illustrating a bend-resistant wire according to an embodiment of the present disclosure;

FIG. 10 is schematic structural diagram 9 illustrating a bend-resistant wire according to an embodiment of the present disclosure;

FIG. 11 is schematic structural diagram 10 illustrating a bend-resistant wire according to an embodiment of the present disclosure;

FIG. 12 is schematic structural diagram 11 illustrating a bend-resistant wire according to an embodiment of the present disclosure;

FIG. 13 is schematic structural diagram 12 illustrating a bend-resistant wire according to an embodiment of the present disclosure;

FIG. 14 is schematic structural diagram 13 illustrating a bend-resistant wire according to an embodiment of the present disclosure;

FIG. 15 is schematic structural diagram 14 illustrating a bend-resistant wire according to an embodiment of the present disclosure;

FIG. 16 is schematic structural diagram 15 illustrating a bend-resistant wire according to an embodiment of the present disclosure;

FIG. 17 is schematic flowchart 1 illustrating a preparation method for a bend-resistant wire according to an embodiment of the present disclosure;

FIG. 18 is schematic flowchart 2 illustrating a preparation method for a bend-resistant wire according to an embodiment of the present disclosure; and

FIG. 19 is a schematic structural diagram illustrating a flexible display panel according to an embodiment of the present disclosure.

Reference numerals: 110: flexible substrate; 120: conductive layer; 121: wire mesh structure; 130: hollow part; 131: through hole; 410: flexible display panel; 420: fan-out region.

### DETAILED DESCRIPTION OF THE INVENTION

To make the objectives, technical solutions and advantages of the embodiments of the present disclosure clearer, the following clearly and completely describes the technical solutions in the embodiments of the present disclosure with reference to accompanying drawings in the embodiments of the present disclosure. Apparently, the described embodiments are some rather than all of the embodiments. Components of the embodiments of the present disclosure generally described and illustrated in the accompanying drawings herein may be arranged and designed in various different configurations.

Therefore, the following detailed description of the embodiments of the present disclosure provided in the accompanying drawings is not intended to limit the claimed scope of the present disclosure, but merely represents selected embodiments of the present disclosure. All other embodiments obtained by a person of ordinary skill in the art based on the embodiments of the present disclosure without creative efforts shall fall within the protection scope of the present disclosure.

It should be noted that similar reference numerals and letters indicate similar terms in the following accompanying drawings. Therefore, once a certain term is defined in one accompanying drawing, it does not need to be further defined and explained in the subsequent accompanying drawings.

In the description of the present disclosure, it should be noted that the terms such as “first”, “second” and “third” are merely used to distinguish between descriptions and cannot be understood as indicating or implying relative importance.

In addition, the terms such as “horizontal” and “vertical” do not mean that a component is required to be absolutely horizontal or overhanging, but may be slightly inclined. For example, “horizontal” only means that its direction is more horizontal than “vertical”, and does not mean that the structure must be completely horizontal, but may be slightly inclined.

In the description of the present disclosure, it should also be noted that, unless otherwise specified and defined, the terms “arrange”, “mount”, “connected to”, “connect”, etc. should be understood in a broad sense, for example, a connection may be a fixed connection, or a detachable connection, or an integrated connection; or a mechanical connection, or an electrical connection; or a direct connection, an indirect connection through an intermediate medium, or internal communication between two elements. For a person of ordinary skill in the art, the specific meanings of the above-mentioned terms in the present disclosure may be understood based on specific conditions.

As people's requirements for the aesthetics and interactive experience of mobile phones and other electronic products continuously increase, display apparatuses with a high screen-to-body ratio have become a hot spot in the display field.

At present, common display apparatuses with a high screen-to-body ratio are generally implemented by using a technology featuring a small bending radius for the lower bezel (the bending radius R is usually less than 0.5 mm), so that the display apparatuses have a reduced width for the lower bezel to further increase the screen-to-body ratio of the display apparatuses. However, because the bezel of the display apparatuses needs to be bent by a small radius, a fan-out wire arranged in a fan-out region of the bezel often breaks due to the bending, resulting in a low yield and poor performance stability of the display apparatuses with a high screen-to-body ratio.

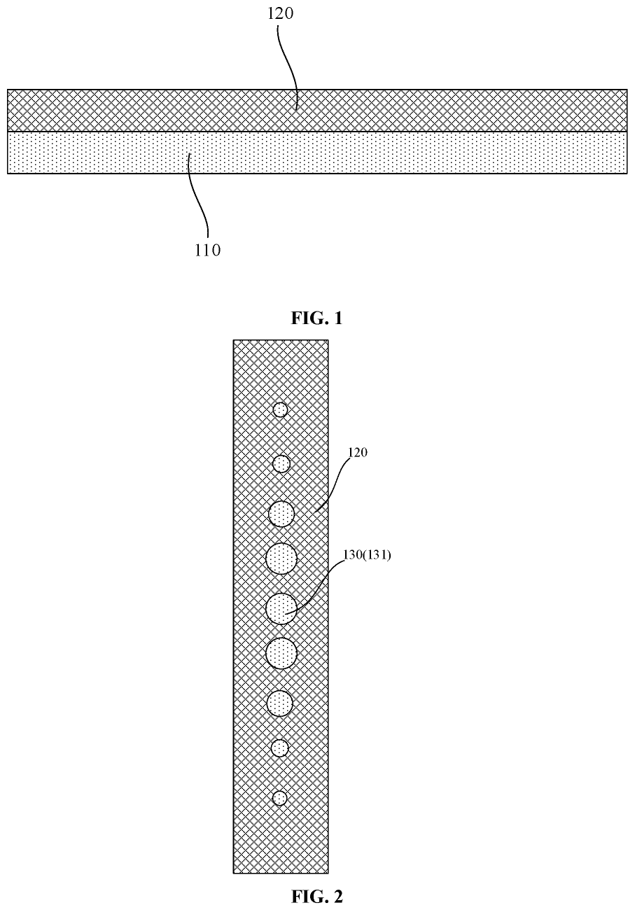

Therefore, an embodiment of the present disclosure provides a bend-resistant wire, which can reduce a risk that a fan-out wire of a flexible display panel breaks when the flexible display panel is bent. Therefore, the product yield and performance stability of a display apparatus with a high screen-to-body ratio are improved. As shown in FIG. 1 and FIG. 19, the bend-resistant wire is formed on a side surface of a flexible substrate 110 of a flexible display panel 410 that is located in a fan-out region 420. The bend-resistant wire includes a conductive layer 120, and the conductive layer 120 has hollow parts 130 formed corresponding to a bent region of the flexible substrate 110 (as shown in FIG. 2).

In practice, the bend-resistant wire may be applied to a flexible display panel 410 adopting chip on plastic (COP) package. For the flexible display panel 410 adopting COP package, a lower bezel thereof with the fan-out region 420 is usually arranged by being bent toward the back of the display panel, so that a drive chip and a flat cable can be arranged on the back side of the display panel, thereby reducing the width of the lower bezel. Because the lower bezel of the flexible display panel 410 is bent, the bend-resistant wire for connecting the drive chip located on the back side of the display panel to a data line and/or a scanning line of the display panel is bent with the bent region that is formed by bending a position of the flexible substrate 110 corresponding to the lower bezel. The bent region of the flexible substrate 110 may usually be in the shape of a semi-ellipse (e.g., a semi-ellipse obtained through cutting by taking a minor axis as a cutting line), a semi-circle or the like, which is not limited herein.

The conductive layer 120 forming the bend-resistant wire may be deposited on the flexible substrate 110 by using methods such as physical vapor deposition (PVD), chemical vapor deposition (CVD) and atomic layer deposition (ALD). Moreover, in practice, it is also possible to design the conductive layer 120 by etching after the entire conductive layer 120 is deposited on the flexible substrate 110, so as to form multiple bend-resistant wires that are routed based on the circuit design. Certainly, alternatively, the conductive layers 120 of the bend-resistant wire may be separately deposited on the flexible substrate 110 in sequence, which is not limited herein.

The conductive layer 120 as the bend-resistant wire may be made of conductive materials such as graphene, metal and indium tin oxide. This is not limited provided that the conductive layer can have good conductivity.

It should be noted that, there may be only one hollow part 130 formed at the position of the conductive layer 120 corresponding to the bent region of the flexible substrate 110, or multiple hollow parts 130 may be arranged in the bent region in a certain pattern, which is not limited herein provided that the conductive layer 120 has the hollow parts 130 formed corresponding to the bent region of the flexible substrate 110.

The bend-resistant wire provided in the embodiment of the present disclosure is formed on the side surface of the flexible substrate 110 of the flexible display panel 410 that is located in the fan-out region 420. In practice, the bend-resistant wire may be routed based on a specific circuit design, so as to use the bend-resistant wire as a fan-out wire to implement communication connection between a drive circuit and a drive chip of the flexible display panel 410. There are multiple bend-resistant wires, which may be connected to multiple scanning lines or multiple data lines on the flexible display panel 410 respectively, or connected to multiple scanning lines and multiple data lines respectively. The bend-resistant wires each are composed of a conductive layer 120, and the conductive layer 120 has hollow parts 130 formed corresponding to a bent region of the flexible substrate 110. The hollow parts 130 formed in the conductive layer 120 can reduce a bending stress borne by a part of the conductive layer 120 in the bent region of the flexible substrate 110 when the flexible substrate 110 is bent. As such, the bending resistance of the bend-resistant wire is improved, and when the flexible substrate 110 is bent, the wire thereon is not prone to breakage, which reduces a risk of poor electrical properties when the flexible substrate 110 (the flexible display panel 410) is bent.

Optionally, an area of each of the hollow parts 130 in the bent region is positively correlated with a curvature of the corresponding bent region.

The curvature of the bent region corresponding to the hollow part 130 in the bent region may be a curvature of a position in the bent region that corresponds to the hollow part 130.

Due to the hollow parts 130 provided in the conductive layer 120, the effect of reducing the bending stress borne by the conductive layer 120 in the bent region of the flexible substrate 110 is related to the area of each of the hollow parts 130. That is, a greater area of each of the hollow parts 130 indicates a smaller bending stress borne by the region in which the hollow parts 130 of the conductive layer 120 are formed. Moreover, because a greater curvature of the bent region of the flexible substrate 110 indicates a greater bending stress generated on the conductive layer 120, the area of each of the hollow parts 130 in the bent region is set to be positively correlated with the curvature of the corresponding bent region, i.e., a greater curvature of the bent region indicates a greater area of each of the hollow parts 130 formed on the conductive layer 120 at the corresponding position, so that the region of the conductive layer 120 in the bent region can always have good bending resistance. Moreover, with a small area of each of the hollow parts 130 corresponding to a position of the flexible substrate 110 with a small bending curvature, the conductive layer 120 can have low electrical resistance (a smaller area of each of the hollow parts 130 indicates a greater conductive part of the conductive layer 120 in a corresponding region and smaller overall electrical resistance in the region) while having good bending resistance at this position, and thus the bend-resistant wire can have good electrical properties in addition to good bending resistance.

The bezel of the flexible display panel 410 may usually be bent based on a center position thereof, i.e., a bending curve of the bent region thereof is in a circular arc or elliptical arc shape (when the bending curve is in the circular arc or elliptical arc shape, the curvature of the central region is greater than a curvature of each of the regions at two ends).

For example, as shown in FIG. 2, the hollow parts 130 formed on the conductive layer 120 corresponding to the bent region may be arranged in such a way that the area of each of the hollow parts 130 in the regions at both ends of the conductive layer 120 is smaller than the area of each of the hollow parts 130 in the central region of the conductive layer 120 in the bending direction of the bent region, so that the area of each of the hollow parts 130 formed on the conductive layer 120 is positively correlated with the curvature of the bent region.

Specifically, the areas of the hollow parts 130 may gradually decrease from the central region to the regions at the two ends of the conductive layer 120. Therefore, the hollow parts 130 may be relatively uniformly arranged in the conductive layer 120, so that the bending stress borne by the conductive layer 120 is relatively uniformly dispersed, and the bending resistance of the conductive layer 120 is further improved.

Optionally, as shown in FIG. 2, the hollow parts 130 are through holes 131 arranged in the conductive layer 120.

The through holes 131 as the hollow parts 130 are arranged in the conductive layer 120 in a certain pattern, or may not need to be arranged, which is not limited herein.

In practice, the through holes 131 may be formed in the conductive layer 120 by etching after the conductive layer 120 is formed. Certainly, the through holes may alternatively be formed by laser drilling or the like, which is not limited herein.

By forming the through holes 131 at corresponding positions of the conductive layer 120 as the hollow parts 130, a process is relatively simple and easy to implement, which can reduce a preparation cost of the bend-resistant wire.

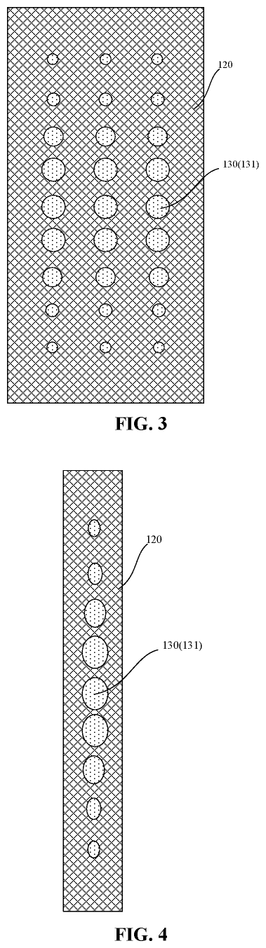

For example, as shown in FIG. 2 and FIG. 3, the through holes 131 may be arranged in the conductive layer 120 in a single column or multiple columns in the bending direction of the bent region, which is not limited herein. Arranging the through holes 131 into multiple columns in the bending direction can better disperse the bending stress borne by the conductive layer 120 at the position corresponding to the bent region, thereby further improving the bending resistance of the bend-resistant wire composed of the conductive layer 120.

Optionally, shapes of the through holes 131 arranged into a single column or multiple columns may be one or a combination of several of a circle, an ellipse, a triangle and a polygon.

Based on the aforementioned embodiment of the hollow parts 130, for example, as shown in FIG. 2 and FIG. 3, the through holes 131 formed in the conductive layer 120 may be a single column or multiple columns of circular through holes 131 arranged in the bending direction of the bent region. Moreover, in the bending direction of the bent region, a diameter of each of the circular through holes 131 in regions at two ends of the conductive layer 120 is smaller than a diameter of each of the circular through holes 131 in a central region of the conductive layer 120.

For example, the through holes 131 formed in the conductive layer 120 may alternatively be a single column or multiple columns of triangular through holes 131, polygonal through holes 131 or elliptical through holes 131 arranged in the bending direction of the bent region. Moreover, in the bending direction of the bent region, the area of each of the through holes 131 in regions at two ends of the conductive layer 120 is smaller than the area of each of the through holes 131 in the central region of the conductive layer 120.

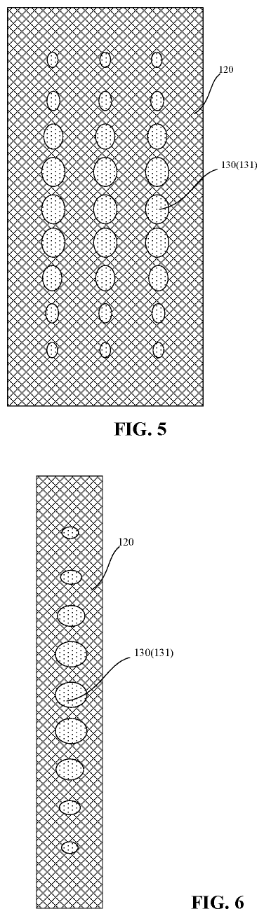

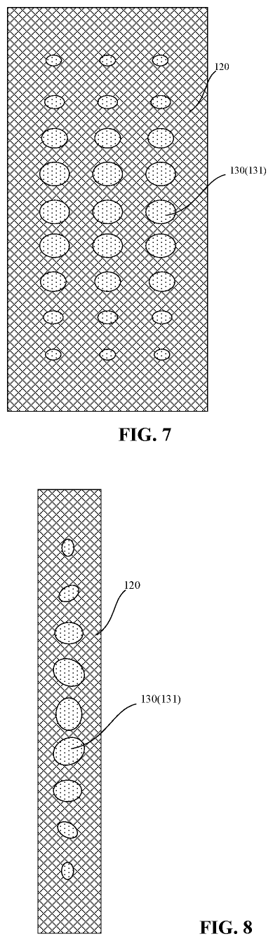

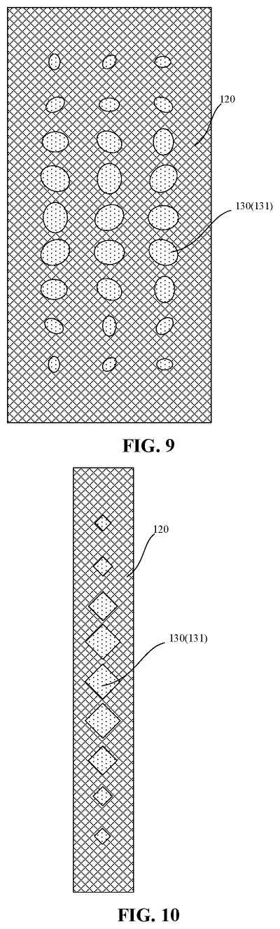

Specifically, as shown in FIG. 4 and FIG. 5, the through holes 131 may be a single column or multiple columns of elliptical through holes 131, and a major axis of each of the elliptical through holes 131 is parallel to the bending direction of the bent region. Certainly, in practice, as shown in FIG. 6 and FIG. 7, the elliptical through holes 131 may alternatively be arranged in such a way that minor axes are separately parallel to the bending direction of the bent region, or as shown in FIG. 8 and FIG. 9, major axes of the elliptical through holes 131 are arranged randomly in direction, which is not limited herein.

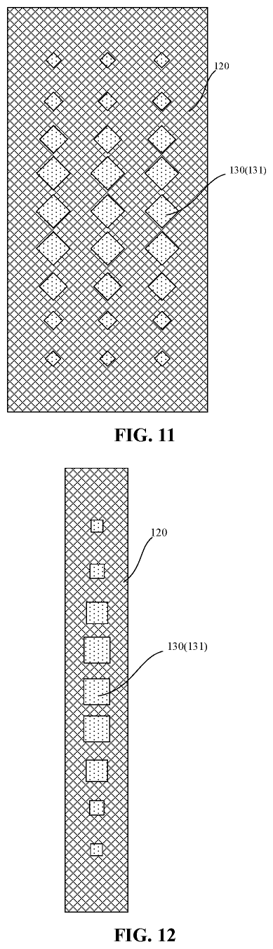

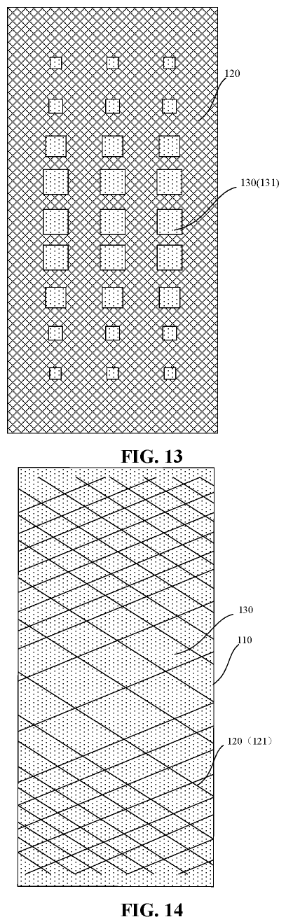

Specifically, as shown in FIG. 10 and FIG. 11, the through holes 131 may alternatively be a single column or multiple columns of square through holes 131, and a diagonal line of each of the square through holes 131 is parallel to the bending direction of the bent region. Certainly, in practice, as shown in FIG. 12 and FIG. 13, each square through hole 131 may alternatively be arranged in such a way that a diagonal line and the bending direction of the bent region form an angle of 45°. Or, a rotation angle of each square through hole 131 is set randomly, which is not limited herein.

Certainly, the descriptions above are only examples of the implementation in which the through holes 131 formed in the conductive layer 120 are used as the hollow parts 130 in the embodiment of the present disclosure. In practice, a person skilled in the art can further adaptively set the specific shapes and arrangements of the through holes 131 based on actual design requirements and conditions. For example, the through holes 131 may alternatively be in other irregular shapes, and may be arranged in an S-shaped line. This is not limited herein, provided that the conductive layer 120 has through holes 131 serving as the hollow parts 130 at positions corresponding to the bent region.

Optionally, as shown in FIG. 14, the conductive layer 120 has a wire mesh structure 121, and meshes of the wire mesh structure 121 are the hollow parts 130.

The conductive layer 120 is arranged into the wire mesh structure 121, and the meshes of the wire mesh structure 121 are used as the hollow parts 130, so that the wire mesh structure 121 can be used to disperse the bending stress borne by the conductive layer 120, thereby further improving the bending resistance of the bend-resistant wire. Moreover, the bend-resistant wire composed of the conductive layer 120 can further have good tensile properties while having relatively good bending resistance, thereby improving its structural resistance.

For example, shapes of the meshes of the conductive layer 120 having the wire mesh structure 121 may include any one of a triangle, a quadrilateral and a hexagon. Certainly, in practice, the meshes may alternatively be in other shapes. A person skilled in the art may arrange the wire mesh structure 121 based on actual needs, which is not limited herein.

Specifically, as shown in FIG. 14, the conductive layer 120 may have a wire mesh structure 121 with quadrilateral meshes, and the mesh density (mesh quantity) of the wire mesh structure 121 gradually increases from a central region toward regions at two ends in the bending direction of the bent region. That is, the size (area) of each mesh in the central region is greater than that of each mesh in the regions at both ends.

In practice, optionally, the conductive layer 120 may include at least two wire layers that are stacked on each other and electrically connected to each other. That is, each wire of the conductive layer 120 having the wire mesh structure 121 may be composed of different wire layers. Certainly, the wire structure may alternatively be composed of one wire layer, i.e., the conductive layer 120 includes one layer in structure. The wire structure may be formed by depositing the conductive layer 120 on the flexible substrate 110 and then etching the conductive layer 120. Certainly, it is also possible to form the conductive layer 120 having the wire mesh structure 121 directly through deposition, which is not limited in the embodiments of the present disclosure.

For example, when the mesh of the wire mesh structure 121 is a parallelogram, two sets of parallel wires that constitute the parallelogram mesh each may be composed of two wire layers. Moreover, the wires that are parallel to each other between the meshes may be composed of the same wire layer. For another example, when the mesh of the wire mesh structure 121 is triangular, three wires that constitute the triangular mesh may be composed of three wire layers respectively. Moreover, the wires parallel to each other between the meshes may be composed of the same wire layer. For another example, when the mesh of the wire mesh structure 121 is hexagonal, three sets of mutually parallel wires that constitute the hexagonal mesh may be composed of three layers of wires respectively. Moreover, the wires parallel to each other between the meshes may be composed of the same wire layer. Certainly, regardless of the mesh shape of the wire mesh structure 121, each wire of the wire mesh structure 121 may alternatively be composed of two or more wire layers according to a certain distribution rule. Therefore, in the embodiment of the present disclosure, no limitation is imposed herein on the number of wire layers that constitute the conductive layer 120 with the wire mesh structure, or specific wires that are composed of the wire layers.

In specific implementation, the wire mesh structure 121 is composed of multiple wire layers. Such practice enables the wire mesh structure 121 to have a high structural strength, so that the bend-resistant wire composed of the conductive layer 120 has better structural strength, thereby improving structural stability.

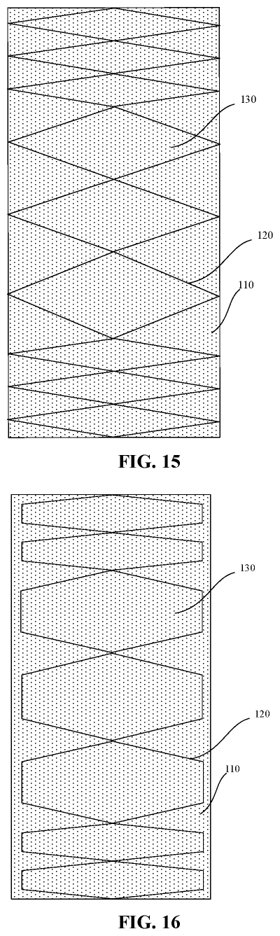

Optionally, as shown in FIG. 15, the conductive layer 120 is composed of multiple rhombic conductive bezels connected in sequence by vertices, regions enclosed by the rhombuses are the hollow parts 130, the rhombuses are arranged in sequence along straight lines where first diagonal lines of the rhombuses are located, and second diagonal lines of the rhombuses are all equal in length, where the first diagonal lines are each parallel to the bending direction of the bent region, and the length of each first diagonal line gradually decreases along a bending line of the bent region (i.e., the central region of the bent region) in the direction away from the bending line.

The conductive layer 120 is disposed as multiple rhombic conductive bezels with vertices connected in sequence, and regions enclosed by the rhombuses are used as the hollow parts 130, so that in specific implementation, different sizes (areas) of the hollow parts 130 can be realized by arranging rhombic conductive bezels with different sizes.

For example, in the conductive layer 120 composed of multiple rhombic conductive bezels with vertices connected in sequence, a perimeter of each of the rhombic conductive bezels located in the central region corresponding to the bent region may be set to be greater than a perimeter of each of the rhombic conductive bezels in the regions at the two ends, so that the area of each of the hollow parts 130 in the central region of the conductive layer 120 is greater than the area of each of the hollow parts 130 in the regions at the two ends.

Certainly, in the embodiment of the present disclosure, the conductive layer 120 may alternatively be disposed as a structure formed by connecting conductive bezels of other geometric shapes in sequence along a straight line. For example, as shown in FIG. 16, the conductive layer may alternatively have a structure formed by connecting multiple hexagons in sequence along a straight line, which is not limited herein.

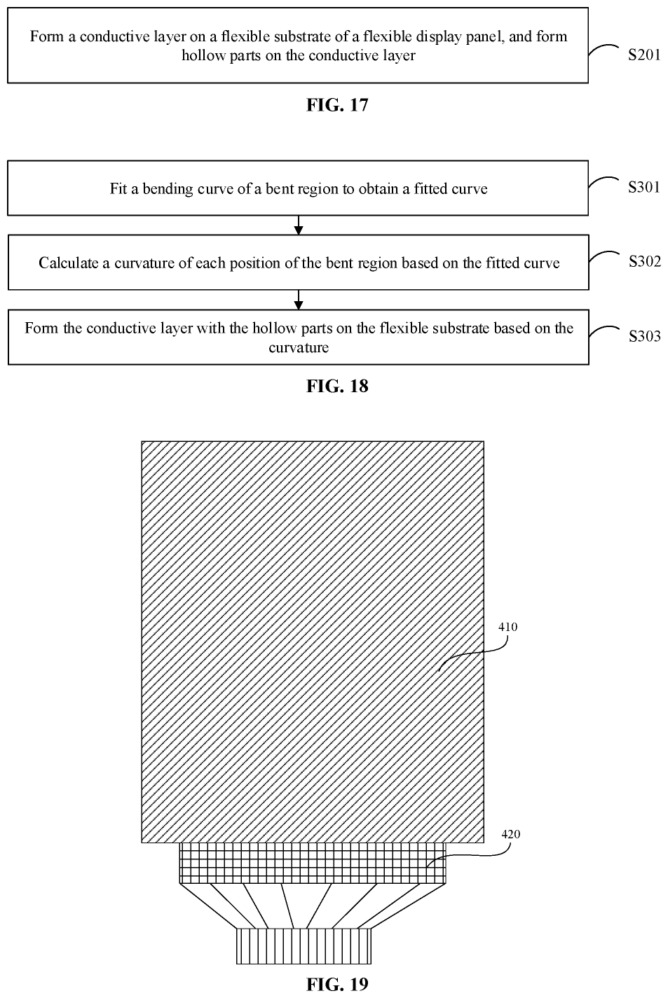

According to another aspect of the embodiments of the present disclosure, a preparation method for a bend-resistant wire is provided, as shown in FIG. 17, including the following steps.

S201: Form a conductive layer 120 on a flexible substrate 110 of a flexible display panel 410, and form hollow parts 130 on the conductive layer 120.

The conductive layer 120 is located in a fan-out region of the flexible display panel 410, the hollow parts 130 correspond to a bent region of the flexible substrate 110, and an area of each of the hollow parts 130 is positively correlated with a curvature of the corresponding bent region.

The conductive layer 120 may be deposited on the flexible substrate 110 by using methods such as PVD, CVD and ALD. Moreover, the hollow parts 130 formed in the conductive layer 120 corresponding to the bent region of the flexible substrate 110 can be obtained by etching the entire formed conductive layer 120 to form through holes 131, or by directly depositing a wire mesh structure 121 with meshes as the conductive layer 120 so as to take the meshes as the hollow parts 130. Certainly, the wire mesh structure 121 may also be formed by etching on the conductive layer 120. No limitation is imposed herein.

In the preparation method for a bend-resistant wire provided in the embodiment of the present disclosure, the conductive layer 120 is formed on the flexible substrate, and the conductive layer 120 has the hollow parts 130 formed corresponding to the bent region of the flexible substrate 110. Such implementation can reduce a bending stress borne by the bend-resistant wire composed of the conductive layer 120 in the bent region, so that the wire has good bending resistance. When the flexible display panel 410 is bent, the wire thereon is not prone to breakage, which reduces a risk of poor electrical properties when the flexible display panel 410 is bent.

Optionally, as shown in FIG. 18, the forming a conductive layer 120 on a flexible substrate 110 of a flexible display panel 410, and forming hollow parts 130 on the conductive layer 120 includes the following steps.

S301: Fit a bending curve of the bent region to obtain a fitted curve.

S302: Calculate a curvature of each position of the bent region based on the fitted curve.

S303: Form the conductive layer 120 with the hollow parts 130 on the flexible substrate 110 based on the curvature.

Curve fitting performed on the bent region of the flexible substrate 110 may be implemented by sampling an image of a bending shape of the flexible substrate 110, and then performing curve fitting on the bending shape based on the obtained image, so as to obtain a curve equation of the bending curve of the bent region, and to facilitate subsequent calculation of a curvature of each position of the bent region based on the curve equation.

For example, a bending curve of a bezel in a flexible display panel may be a semi-ellipse, i.e., a curve obtained through cutting by taking a minor axis as a cutting line. Therefore, it can be learned from a standard curve equation of an ellipse that, a curvature radius of a central region of the bending curve is a²/b, and a curvature radius of each of regions at two ends is b²/a, where a is a semi-major axis of the ellipse, and b is a semi-minor axis of the ellipse. It can be learned from the standard curve equation of an ellipse that, a is less than b. Therefore, the curvature radius of the central region of the bending curve is greater than that of each of the regions at the two ends. Therefore, the hollow parts 130 formed on the conductive layer 120 may be arranged in such a way that the area of each of the hollow parts 130 in the regions at the two ends is smaller than the area of each of the hollow parts 130 in the central region in the bending direction of the bent region.

It should be noted that a person skilled in the art can clearly understand that, for ease and simplicity of description, for specific implementations and beneficial effects of the conductive layer 120 and the hollow parts 130 formed thereon involved in the preparation method for a bend-resistant wire described above, reference may be made to the corresponding explanations and descriptions in the foregoing embodiment of the bend-resistant wire, and details are not repeated in the present disclosure.

According to still another aspect of the embodiments of the present disclosure, a flexible display panel is provided. As shown in FIG. 19, the bend-resistant wire according to any one of the above implementations is used as a fan-out wire in a fan-out region 420 of the flexible display panel 410.

The above-mentioned bend-resistant wire can reduce the bending stress borne by the conductive layer 120 at the bent region, thereby having good bending resistance. Therefore, the above-mentioned bend-resistant wire is used as the fan-out wire, so that when the flexible display panel 410 is bent, the bend-resistant wire (the fan-out wire) thereon is not prone to breakage, which reduces a risk of poor electrical properties when the flexible display panel 410 is bent, thereby having good product performance and yield.

The foregoing descriptions are only preferred embodiments of the present disclosure and are not intended to limit the present disclosure. For a person skilled in the art, various modifications and changes may be made to the present disclosure. Any modification, equivalent replacement, improvement and the like made within the spirit and principle of the present disclosure shall fall within the protection scope of the present disclosure.

1. A bend-resistant wire, wherein the bend-resistant wire is formed on a side surface of a flexible substrate of a flexible display panel that is located in a fan-out region, the bend-resistant wire comprises a conductive layer, the conductive layer has hollow parts formed corresponding to a bent region of the flexible substrate, and an area of each of the hollow parts in the bent region is positively correlated with a curvature of the corresponding bent region.

2. The bend-resistant wire according to claim 1, wherein in a bending direction of the bent region, the area of each of the hollow parts in regions at two ends of the conductive layer is smaller than the area of each of the hollow parts in a central region of the conductive layer.

3. The bend-resistant wire according to claim 2, wherein the areas of the hollow parts gradually decrease from the central region to the regions at the two ends of the conductive layer.

4. The bend-resistant wire according to claims 1, wherein the hollow parts are through holes arranged in the conductive layer.

5. The bend-resistant wire according to claim 4, wherein the through holes are arranged in multiple columns in the bending direction of the bent region.

6. The bend-resistant wire according to claim 4, wherein shapes of the through holes are one or a combination of several of a circle, an ellipse, a triangle and a polygon.

7. The bend-resistant wire according to claim 1, wherein the conductive layer has a wire mesh structure, and meshes of the wire mesh structure are the hollow parts.

8. The bend-resistant wire according to claim 7, wherein shapes of the meshes comprise any one of a triangle, a quadrilateral and a hexagon.

9. The bend-resistant wire according to claim 7, wherein the conductive layer comprises at least two wire layers stacked on each other.

10. The bend-resistant wire according to claim 1, wherein the conductive layer is composed of multiple rhombic conductive bezels connected in sequence by vertices, regions enclosed by the rhombuses are the hollow parts, the rhombuses are arranged in sequence along straight lines where first diagonal lines of the rhombuses are located, and second diagonal lines of the rhombuses are all equal in length, wherein the first diagonal lines are each parallel to the bending direction of the bent region.

11. The bend-resistant wire according to claim 2, wherein the conductive layer is composed of multiple rhombic conductive bezels connected in sequence by vertices, regions enclosed by the rhombuses are the hollow parts, the rhombuses are arranged in sequence along straight lines where first diagonal lines of the rhombuses are located, and second diagonal lines of the rhombuses are all equal in length, wherein the first diagonal lines are each parallel to the bending direction of the bent region.

12. The bend-resistant wire according to claim 3, wherein the conductive layer is composed of multiple rhombic conductive bezels connected in sequence by vertices, regions enclosed by the rhombuses are the hollow parts, the rhombuses are arranged in sequence along straight lines where first diagonal lines of the rhombuses are located, and second diagonal lines of the rhombuses are all equal in length, wherein the first diagonal lines are each parallel to the bending direction of the bent region.

13. A preparation method for a bend-resistant wire, comprising:
forming a conductive layer on a flexible substrate of a flexible display panel, and forming hollow parts on the conductive layer, wherein the conductive layer is located in a fan-out region of the flexible display panel, the hollow parts correspond to a bent region of the flexible substrate, and an area of each of the hollow parts in the bent region is positively correlated with a curvature of the corresponding bent region.

14. The preparation method according to claim 13, wherein the forming a conductive layer on a flexible substrate of a flexible display panel, and forming hollow parts on the conductive layer comprises:
fitting a bending curve of the bent region to obtain a fitted curve;
calculating a curvature of each position of the bent region based on the fitted curve; and
forming the conductive layer with the hollow parts on the flexible substrate based on the curvature.

15. The preparation method according to claim 14, wherein curve fitting performed on the bent region of the flexible substrate may be implemented by sampling an image of a bending shape of the flexible substrate, and then performing curve fitting on the bending shape based on the obtained image, so as to obtain a curve equation of the bending curve of the bent region, and to facilitate subsequent calculation of a curvature of each position of the bent region based on the curve equation.

16. The preparation method according to claim 15, wherein the hollow parts formed on the conductive layer may be arranged in such a way that the area of each of the hollow parts in the regions at the two ends is smaller than the area of each of the hollow parts in the central region in the bending direction of the bent region.

17. A flexible display panel, a bend-resistant wire is used as a fan-out wire in a fan-out region of the flexible display panel;
wherein the bend-resistant wire is formed on a side surface of a flexible substrate of a flexible display panel that is located in a fan-out region, the bend-resistant wire comprises a conductive layer, the conductive layer has hollow parts formed corresponding to a bent region of the flexible substrate, and an area of each of the hollow parts in the bent region is positively correlated with a curvature of the corresponding bent region.
